(19) United States
(12) Patent Application Publication
(10) Pub. No.: US 2005/0112791 A1
(43) Pub. Date: May 26, 2005

(54) Method and apparatus for fabricating commercially feasible and structurally robust nanotube-based nanomechanical devices

(76) Inventors: Robert C. Davis, Provo, UT (US); Jed Whittaker, Louisville, CO (US); Matthew R. Linford, Orem, UT (US)

Correspondence Address: KIRTON & McCONKIE, 1800 Eagle Gate Tower, 60 East South Temple, Salt Lake City, UT, 84111, US

(21) Appl. No.: 10/955,259

(22) Filed: Sep. 30, 2004

Related U.S. Application Data
(60) Provisional application No. 60/507,666, filed on Sep. 30, 2003.

(51) Int. Cl. H01L 21/00; G21K 7/00; G01N 23/00; H01L 29/84

(52) U.S. Cl. 438/50; 257/415

(57) ABSTRACT

A method and device for providing structurally robust and commercially feasible nanotube-based nanomechanical devices is provided. Specifically, a method of fabricating a carbon nanotube that is securely attached to a substrate, or atomic force microscopy tip, is provided by a process that uses silicide and palladium to secure the carbon nanotube to a commercially produced AFM cantilever, as well as self-aligning thin film deposition techniques.

### 1. RELATED APPLICATION INFORMATION

This application claims the benefit of priority to Provisional Patent Application No. 60/507,666, filed Sep. 30, 2003, which application is hereby incorporated by reference in its entirety.

### 2. FIELD OF INVENTION

The present invention relates to a method and device used for the fabrication of structurally robust nanotube-based nanomechanical devices. Specifically, the present invention provides a method and device for fabricating nanotube-based nanomechanical devices that not only demonstrates an extraordinarily strong attachment between the nanotubes and the surfaces to which they are attached, but is also more capable of mass fabrication than techniques currently available.

### BACKGROUND

Carbon nanotubes display unique properties¹ making them ideal for various applications. They have high aspect ratios and a Young's modulus of approximately 1 Tpa, characterizing unique strength, ideal electrical properties, and extraordinary mechanical resilience. Moreover, these properties make them ideal for force measurements and for imaging steep-walled features. Applications using carbon nanotubes include cantilever beam flexural oscillators in the megahertz range² and atomic
¹Wong E., Sheehan P., Lieber.; Science 1997, 277, 1971.

²Poncharal P., Wang, Z., Ugarte D., de Heer W.; Science 1999, 283, 1513

force microscopy as probe tips³. In fact, carbon nanotube use in atomic force microscopy is increasingly prevalent because it enables optimal high-resolution imaging.

Atomic force microscopy is a relatively new and rapidly developing technique for imaging the nanometer scale topography of surfaces. Since its development in 1986, it has found great utility in fields ranging from semiconductor fabrication to membrane biology. In biological studies, for example, this data aids understanding of the function of nanometer scale molecular structures, an understanding that ultimately contributes to medicine. The need for nanometer scale microscopy is also increasing in the semiconductor industry. Atomic force microscopy is now finding widespread use in this industry for critical dimension metrology, surface roughness measurements and particulate contamination detection.

As background, atomic force microscopy uses a raster scanned probe to image surface topography. A typical atomic force microscopy cantilever is flexible and consists of a probe with a microscopic tip. The tip is brought very close to a surface, where it experiences inter-atomic forces. The force on the tip causes the cantilever to bend. A laser beam then reflects off the top surface of the cantilever and senses the end of the cantilever. As the probe is raster scanned across the surface, it follows the ups and downs of the surface. In other words, the surface topography is followed and recorded by a computer that monitors the bending of the cantilever. A computer controls the raster scanning of the probe and displays the recorded topographic image. Atomic force microscopy holds great promise as a powerful imaging tool at the molecular level. Its excellent vertical resolution allows it to detect height changes of less than 0.1
³Hafner J., Cheung C., Oosterkamp T., Lieber C., J. Phys. Chem. B 2001, 105, 743

nanometers. Moreover, it can be performed under fluid at close to physiologic conditions.

Though atomic force microscopy is a powerful imaging tool with excellent vertical resolution that can be performed even under fluid conditions, it has limitations. Specifically, at this point in time, lateral resolution of commercial atomic force microscopy is significantly less than its vertical resolution. The major factor currently limiting atomic force microscopy lateral resolution is the radius of curvature of the end of the atomic force microscopy tip. Current commercial atomic force microscopy tips are made from silicon or silicon nitride and have a radius of curvature between 5 and 40 nm. The large discrepancy is due to uncontrolled fluctuations occurring in the manufacturing process.

In an attempt to overcome the deficiencies of silicon-based atomic force microscopy tips, methods for producing and using carbon nanotube-based atomic force microscopy tips with a radius of curvature much smaller than commercial tips are increasingly utilized. In fact, atomic force microscopy probes based on carbon nanotubes results in resolutions ten times better than found in non-carbon nanotube-based probes. The improved resolution is due to the small single wall carbon nanotubes having diameters less than 0.5 nm that are ideal for imaging, because the tip should be as precise as the object under investigation. These ultra-sharp probes significantly impact atomic force microscopy, and various written articles detail their potential impact in the biology and semiconductor industry.⁴
⁴ Cheung, C. L., Hafner, J. H., Lieber, C. M.; PNAS, 97, 3809 (2000); Dai, H., Hafner, J. H., Rinzler, A. G., Colbert, D. T., Smalley, R. E.; Nature, 384, 147 (1996)

A recent advance in the development of nanotube-based probes involves the growth of carbon nanotubes directly on silicon atomic force microscopy probes by chemical vapor deposition.⁵ This procedure, first published in October 1999, directly grows tubes on commercially produced silicon atomic force microscopy tips through chemical vapor deposition. The procedure entails dipping commercial probes into a suspension of colloidal catalyst, then placing them in a tube furnace heated to 750° C. under a flow of hydrogen and argon. When the furnace reaches the target temperature, a small amount of ethylene is added and nanotubes grow from the catalyst particles. Experiments show that in about 90% of cases, a tube protrudes from the silicon tip apex.

Though a significant improvement above silicon-based tips, carbon nanotube-based tips are also not without limitations. A weak Van der Waals attraction holds the nanotube to the silicon tip, (or in non-atomic force microscopy applications, to a substrate), which renders it problematic for imaging in fluid where most biological atomic force microscopy imaging is performed.

To overcome this lack of a rigid attachment between the nanotubes to atomic force microscopy probe tips, one method⁶ uses an acrylic adhesive obtained from briefly sticking the probe tip to carbon tape before manually attaching the tube. Another method⁷ involves welding a nanotube onto a silicon atomic force microscopy probe tip using a scanning electron microscope (SEM) beam. Though these methods produce rigid attachment, they are time consuming and yield nanotube probes with inconsistent and variable lengths and diameters.
⁵Dai, H., Hafner, J. H., Rinzler, A. G., Colbert, D. T., Smalley, R. E.; Nature, 384, 147 (1996) and Hafner, J. H., Cheung, C. L., Lieber, C. M., J. Am. Chem. Soc., 121, 9750 (1999)

⁶Dai H., Hafner J., Rinzler A., Colbert D., Smalley R.; Nature 1996, 384, 147.

⁷Akita S., Nishijima H., Nakayama Y., Tokumasu F., Takeyasu K.; J. Phys. D: Appl. Phys. 1999, 32, 1044

Also, since the above methods sometimes yield nanotubes protruding from the silicon tip apex that are too long, and therefore, too flexible for ideal imaging, they are individually shortened using an electrical cleaving process. This precludes the chemical vapor deposition process from being readily scalable to mass production, because the shortening process is slow and performed one probe at a time. Hence, current nanotube fabrication processes are unsuitable and not feasible for commercial probe manufacturing.

Moreover, in nanomechanical device fabrication, there is difficulty securely attaching nanotubes to three-dimensional structures. Thus, there remains a need for nanomechanical fabrication techniques and devices that are capable of mass fabrication, produce consistent nanotube lengths, result in a rigid attachment between the nanotube and the surface to which it is attached, and that enable fluid imaging where rigid attachment to the tip is critical.

### SUMMARY AND OBJECTS OF THE INVENTION

Some embodiments of the present invention provide a method and device for nanotube-based nanomechanical devices that are: capable of mass fabrication; yield rigid attachments between the nanotubes and the substrates to which they are attached; result in rigid nanotube attachment on three-dimensional structures; produce nanotube probes with consistent lengths and diameters; and in the atomic force microscopy context, enable fluid imaging where rigid attachment of the nanotube to an atomic force microscopy tip is critical.

One embodiment provides a self-aligned thin-film deposition method, involving mechanical attachment of carbon nanotubes to surfaces that result in structurally robust nanotube-based nanomechanical devices. Also, this embodiment is capable of mass fabrication of nanotube-based atomic force microscopy probes and aids in making them available to a wider range of researchers. As an overview, in this embodiment, single-walled carbon nanotubes are grown by thermal chemical vapor deposition across 150 nm wide silicon dioxide trenches, where they are mechanically attached to the trench tops by selective silicon tetra acetate based silicon dioxide, or similarly suitable film, through chemical vapor deposition. Because the film deposited does not cover the portion of the nanotubes where they are suspended across the trenches, the diameter of the nanotube is not increased and its nanomechanical properties are preserved.

The above embodiment of the present invention yields an improved nanomechanical fabrication process and device. Not only does it yield a rigid attachment between the nanotube and a surface and is capable of mass fabrication, but also, it is: more accurate than techniques used currently, such as lithography; more useful on three-dimensional structures where traditional lithography is difficult; and valuable for producing nanotube atomic fabrication microscopy tips for fluid imaging where rigid attachment to the atomic force microscopy is critical.

In another embodiment of the present invention, a new class of carbon nanotube-based atomic force microscopy probes that overcomes the aforementioned limitations of existing nanotube-based probes is described. Specifically, in this embodiment, probes may be manufactured having very short (i.e., 3-8 nanometer) single-walled nanotubes protruding from the end of a silicon or silicon nitride atomic force microscopy tip, by using a palladium silicide thin film deposition technique, along with a subsequent silicide-etching step. A similarly suitable thin film other than palladium silicide may also be used. The probes are fabricated in a complete process capable of mass fabrication.

Accordingly, it is an object of some embodiments of the present invention to use self-aligning thin-film deposition techniques to rigidly attach a nanotube to a surface that overcomes the difficulties of individual nanotube attachment.

It is another object of some embodiments of the present invention to use self-aligning thin-film deposition techniques to rigidly attach a nanotube to a surface in order to define nanoscale features on atomic force microscopy probe tips.

It is yet another object of some embodiments of the present invention to use self-aligning thin-film deposition techniques that produce pattern layers in registration with nanotube contacts.

It is even another object of some embodiments of the present invention to use self-aligning thin-film deposition techniques that are useful on three-dimensional structures where traditional lithography is difficult.

Another object of some embodiments of the present invention provides a process and device that yields a secure attachment between a nanotube and a surface to which the nanotube is attached, and is also capable of mass fabrication.

It is a further object of some embodiments of the present invention to provide a process and device that makes mass fabrication of carbon nanotube-based atomic force microscopy probes possible.

Yet another object of some embodiments of the present invention provides a process and device that does not require nanotube based atomic force microscopy probes to be individually shortened prior to imaging.

An even further object of some embodiments of the present invention provides a carbon nanotube-based atomic force microscopy probe capable of fluid imaging.

These and other objects of the present invention will become more fully apparent from the following description, drawings, and claims. Other objects will likewise become apparent from the practice of the invention as set forth hereafter.

### BRIEF DESCRIPTION OF THE DRAWINGS

The foregoing and other objects and features of the present invention will become more fully apparent from the accompanying drawings when considered in conjunction with the following description and appended claims. Although the drawings depict only typical embodiments of the invention and are thus not deemed limiting of the invention's scope, the accompanying drawings help explain the invention in added detail.

FIG. 1 depicts one embodiment of the present invention portraying the self-aligning thin-film attachment method and device. Specifically, FIG. 1(a) depicts a 40 by 150 nm trench lithographically produced on a SiO₂ substrate. FIG. 1(b) depicts a carbon nanotube grown over the trench by thermal chemical vapor deposition. FIG. 1(c) depicts the substrate selectively coated with SiO₂ by a thermal chemical vapor deposition process, wherein the suspended nanotube is not coated. A similarly appropriate substance to SiO₂ may also be used as the selective coat.

FIG. 2 depicts the same embodiment of FIG. 1 and displays the heating apparatus for silicon dioxide (or similar substance) thermal chemical vapor deposition.

FIG. 3, also from the same embodiment of FIG. 1, depicts XPS data of native oxide (3(a)) and deposited oxide (3(b)), showing, among other things, that after deposition, an increase in strength of the SiO₂ peak is indicated and thus, indicating the deposited layer was SiO₂. Alternatively, if using a film other than SiO₂, analogous results would be produced.

FIG. 4, also from the same embodiment of FIG. 1, depicts an atomic force microscopy image of a carbon nanotube grown by chemical vapor deposition over the trenches in SiO₂.

FIG. 5, also from the same embodiment of FIG. 1, depicts a nanotube buried in SiO₂ FIG. 5(a) is an atomic force microscopy height image, scale bar 125 nm. FIG. 5(b) is a SEM image. FIG. 5(c) is a coaxial line scan of a nanotube buried in SiO₂ and suspended over a trench from the image taken in 5(a). FIG. 5(d) depicts atomic force microscopy cross-sectional height measurements showing the distance from the top of the nanotube to the top of the trench as 8.2 nm.

FIG. 6, also from the same embodiment of FIG. 1, is a table displaying the deposition rate trials for times from 10-40 minutes.

FIG. 7 is a typical arrangement of an atomic force microscopy probe imaging a surface.

FIGS. 8(a), (b), (c), (d), (e), and (f) depict another embodiment using a silicide process for attaching and shortening atomic force microscopy cantilevers.

### DETAILED DESCRIPTION OF THE PREFERRED EMBODIMENTS

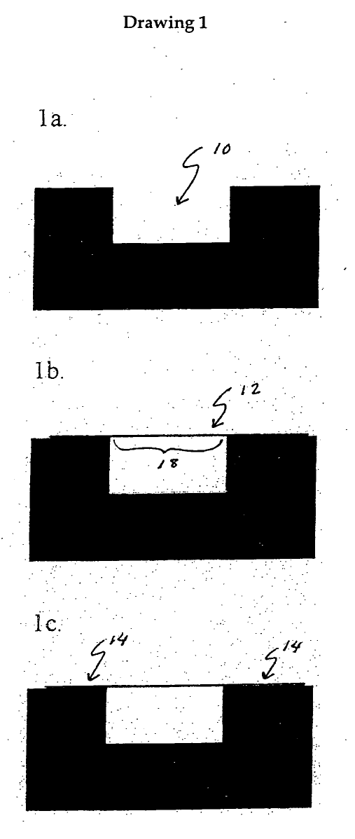

It will be readily understood that the components of the present invention, as generally described and illustrated in the figures herein, could be arranged and designed in a wide variety of different configurations. Thus, the following more detailed description of the embodiments of the system, device and method of the present invention, and represented in FIGS. 1 through 8, is not intended to limit the scope of the invention, as claimed, but is merely representative of the presently preferred embodiments of the invention.

The presently preferred embodiments of the invention will be best understood by reference to the drawings wherein like parts are designated by like numerals throughout.

FIG. 1 illustrates an overview of the method and device of one embodiment of the present invention. Specifically, FIG. 1 depicts the method for attaching a carbon nanotube 12 to a surface or substrate 16 using the technique of self-aligned thin-film deposition. First, as background, self-alignment methods are currently a key technology in silicon device manufacturing⁸ and benefit nanomechanical fabrication processes because they: produce patterned layers without additional lithography steps; provide more accurate alignment than lithography; and are useful on three-dimensional structures where traditional lithography is difficult. Consequently, self-aligning thin-film deposition techniques to secure rigid attachments to surfaces are especially useful for defining nanoscale features on atomic force microscopy probe tips.

In the first step of the embodiment depicted in FIG. 1(a), a trench 10 is lithographically produced. Trenches 10 are produced by e-beam lithography in poly(methyl methacrylate) that is spun onto a SiO₂ substrate 16. Dry etching is used to
⁸Kerwin R., Klein D.; U.S. Pat. No. 3,475,234 1969

transfer the pattern into the SiO_{2,} resulting in trenches (10) 150 nm wide and 40 nm deep. Next, a nanotube 12 is grown over the trench 10 (FIG. 1(b)) and a SiO₂ film 14, or similarly suitable film, is selectively deposited over the trench 10 (FIG. 1(c)) to rigidly attach the nanotube 12. The SiO₂ film 14, or similarly suitable film, is selectively deposited on the SiO₂ substrate 16, so as to not cover the nanotube 12 where it is suspended 18 over the trench 10. This results in a self-aligned attachment of the nanotube 12 where it contacts the SiO₂ substrate 16. If this method were non-selective, the SiO₂ film 14, or similarly suitable film, would coat the nanotube 12 in the suspended region 18, increasing its diameter and altering its nanomechanical properties.

The following describes the method in greater detail. A trenched wafer is dipped into a 150 μg/ml ferric nitrate nonhydrate in isopropyl alcohol catalyst solution⁹. Carbon nanotubes 12 are then grown on the trench 10 sample by chemical vapor deposition (CVD) at 700° C. The chemical vapor deposition is done at atmospheric pressure with flow rates of 150 sccm argon, 100 sccm hydrogen and 5.5 sccm ethylene for six minutes. The SiO₂ film 14, or similarly suitable film, is thermally deposited from a silicon tetra acetate precursor in the reaction¹⁰ Si(O(O)CCH₃)₄(g)→SiO₂(s)+2(CH₃CO)₂O(g), which occurs at 170° C. The (CH₃CO)₂O, or acetic anhydride (b.p. 138-140° C.), is volatile and not incorporated into the film. The silicon tetra acetate is heated to 100° C., just below its 111-114° C. melting point, while the nanotube-trench sample is held at 170° C. The pressure at the silicon tetra acetate source and the silicon sample surface are both 120 mTorr. Ambient air with relative humidity of 25% is flowed into the chamber at 10 scfm.
⁹Hafner, J., Cheung C., Oosterkamp T., Lieber C.; J. Phys. Chem. B 2001, 105, 743

¹⁰Maruyama T., Shionoya J.; Jpn. J. Appl. Phys. 1989, 28, L2253.

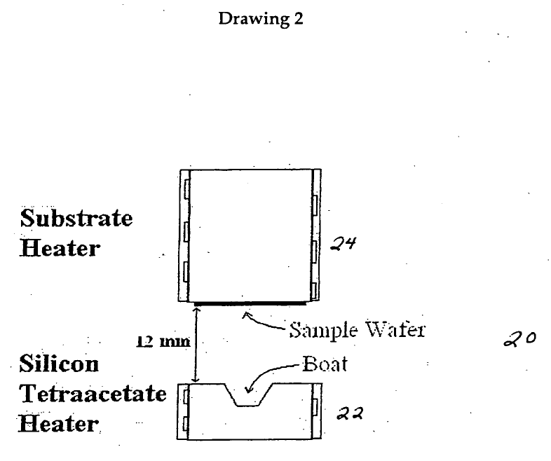

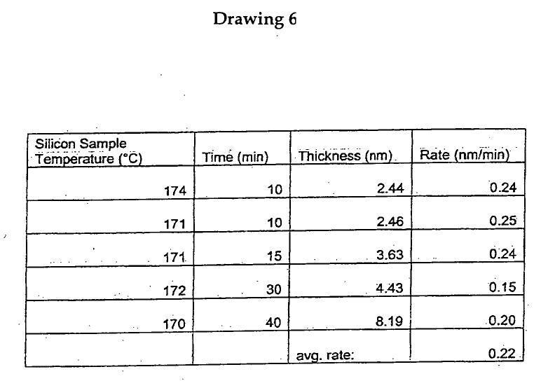

FIG. 2 depicts a two stage heating process 20 specially designed for this chemical vapor deposition process. Each heater 22, 24 is connected to a variable voltage DC power supply and has a thermocouple to monitor temperature. The distance between the wafer substrate and the precursor sample is 12 mm. A shutter separates the wafer substrate and precursor sample and is removed during deposition. This allows precise timing of film 14 growth by blocking deposition until the heaters 22, 24 warm to operating temperature. The rate of SiO₂ film 14, or similarly suitable film, growth is 0.2 nm/min, as determined by variable angle spectroscopic ellipsometry (M-2000, J.A. Woollam Co.) (FIG. 6).

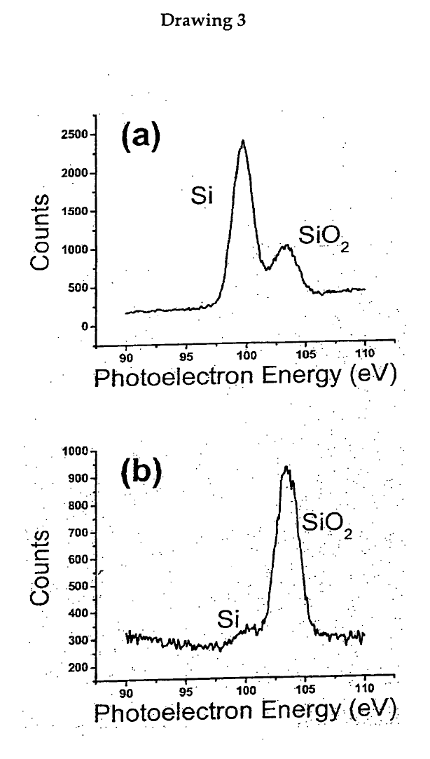

Composition, chemical bonding and film thickness of the deposited SiO₂ film 14, or similarly suitable film, may be studied using an SSX-100 x-ray photoelectron spectrometer with an aluminum kα monochromatic source and a hemispherical analyzer, as is partially illustrated in FIG. 3. The relative areas of the Si 2p peaks from bulk silicon and SiO₂ are used to calculate the film (or analogous film) thickness (14) using standard XPS theory¹¹. Literature values for the mean free paths of Si 2p photoelectrons in silicon (1.6 nm) and SiO₂ (2.6 nm) are used in these calculations^{12,13}.

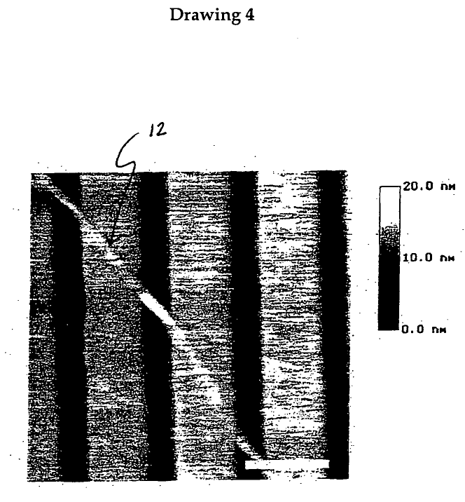

In order to obtain values for the carbon nanotubes 12 after SiO₂ film 14, or similarly suitable film, deposition, the sample may be examined by a Digital Instruments Dimension 3100 atomic force microscopy and a Philips XL 30S FEG SEM. Nanotube 12 diameter is determined by measuring height in atomic force microscopy cross-sectional analysis (FIG. 4).
¹¹Fadley C., Baird R., Siekhaus A W., Novakov T., Berstrom S.; J. Electron Spectrosco. 1974, 4, 93.

¹²Hochella M., Carim A.; Surf. Sci. 1988, 197, L260

¹³Suzuki M., Ando H., Higashi Y., Takenaka H., Shimada H., Matsubayashi N., Imamura M., Kurosawa S., Tanuma S., Powell C.; Surf. Interface Anal. 2000 29, 330

Specifically, in FIG. 4, an atomic force microscopy image of one of several carbon nanotubes 12 is displayed that was grown by chemical vapor deposition and spanned several trenches 10 in the SiO₂ substrate 16. Landmarks near the nanotube 12 were recorded so that this specific tube could be located again and studied after SiO₂ film 14, or similarly suitable film, deposition. The carbon nanotube 12 was measured by atomic force microscopy and found to be 1.9 nm in diameter. (Scale bar is 250 nm.) On top of the trench 10 and carbon nanotubes 12, 11.8 nm of SiO₂ was deposited by chemical vapor deposition and left for 55 minutes at 172° C.

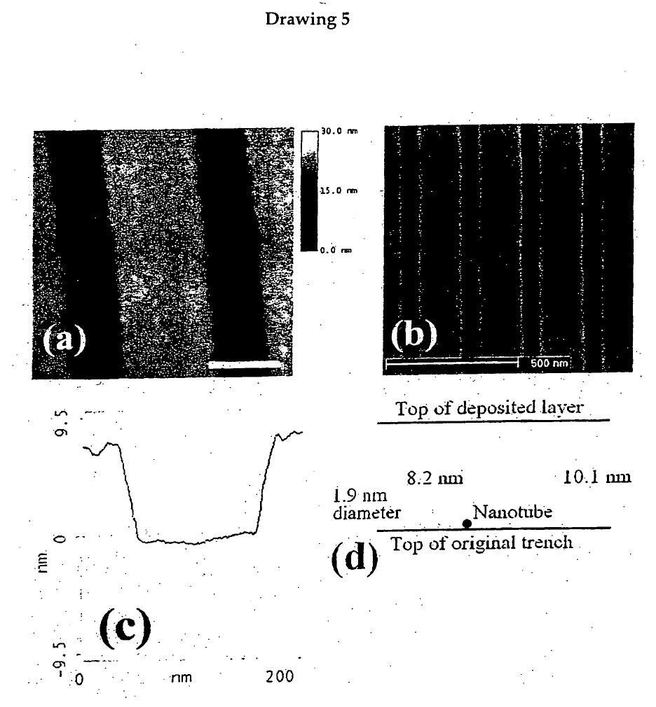

FIG. 5 illustrates features and properties of a nanotube 12 buried in the SiO₂ substrate 16. FIG. 5(a) shows the sample imaged with atomic force microscopy while FIG. 5(b) shows the sample imaged with SEM. Atomic force microscopy height measurements show a difference of 8.2 nm between the top of the nanotube 12 and the top of the trenches 10. This is presented in FIG. 5(c). These atomic force microscopy height measurements are in agreement (20% lower) with ellipsometry thickness measurements.

In FIG. 5(c), the atomic force microscopy line scan shows that the SiO₂, or in other embodiments, a similarly suitable film, was deposited on the top of the trenches 10, but not on the top of the suspended portion 18 of the nanotube 12. This confirms that selective SiO₂ deposition is achieved and is achievable for deposition of similarly suitable films. Thus, silicon tetra acetate-based SiO₂ (or similarly suitable) chemical vapor deposition provides a self-aligned method to rigidly attach carbon nanotubes to SiO₂ structures. Other oxide structures are also compatible with this process, and the embodiments of the present invention are not limited as such. The self-aligned nature of the foregoing process allows rigid nanotube attachment on three-dimensional SiO₂ structures; such as atomic force microscopy probe tips. This process is also compatible with mass fabrication of nanotube atomic force microscopy probes, and aids in making them available to a wider range of researchers. This process is particularly valuable for producing nanotube atomic force microscopy tips for fluid imaging where rigid attachment to the tip is critical.

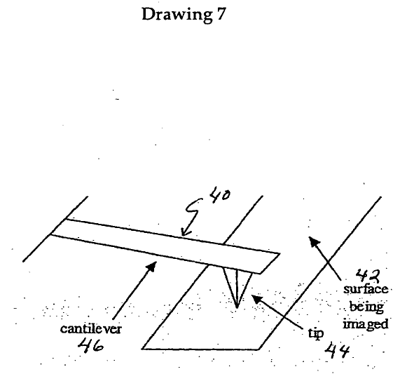

FIG. 7 depicts another embodiment of the method and device used to develop commercially feasible carbon nanotube probes for high-resolution atomic force microscopy. Specifically, FIG. 7 depicts typical atomic force microscopy probe 40 imaging a surface 42. The probe 40 consists of a microscopic tip 44 attached to a flexible cantilever 46. The tip 44 is brought very close to the surface 42, where it experiences inter-atomic forces. The force on the tip 44 causes the cantilever 46 to bend. A laser beam is reflected off the top surface of the cantilever 46 and is used to sense the bending of the cantilever 46. As the probe 40 is raster scanned across the surface, it follows the ups and downs of the surface 42. These ups and downs (i.e., the surface 42 topography) are recorded by a computer that monitors the cantilever's 46 bending. A computer controls the raster scanning of the probe 40 and displays the recorded topographic image.

As mentioned previously, atomic force microscopy's excellent vertical resolution allows detection of height changes of less than 0.1 nanometers and can be performed under fluid at close to physiologic conditions. However, typical atomic force microscopy tips, which are made from silicon or silicon nitride, have a relatively large radius of curvature. This results in poor lateral resolution.

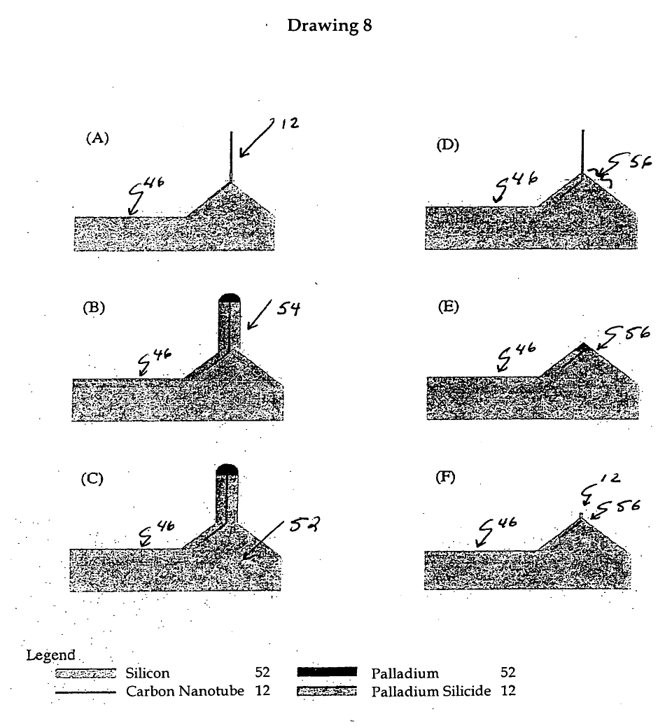

This embodiment of the present invention, as depicted in FIG. 8, provides a method and device overcoming the above-mentioned limitations of existing nanotube-based probes. Specifically, in this embodiment, small single-walled carbon nanotubes 12 may be produced having diameters less than 0.5 nm and are very short, 3-8 nm. These single-walled carbon nanotubes 12 protrude from the end of a silicon or silicon nitride atomic force microscopy tip 44.

Generally, as shown in FIG. 8, the method of this embodiment uses a palladium silicide 56 thin film deposition to rigidly attach the nanotube 12. A similarly appropriate thin film may also be used. A subsequent silicide-etching step is then used to controllably expose a 3-8 nm length of nanotube 12. Specifically, a carbon nanotube 12 (FIG. 8(a)) is grown on a silicon atomic force microscopy tip 42. A 5 nm palladium layer 54 (FIG. 8(b)) is then deposited by thermal evaporation, where an interface is created between the palladium layer 54 and the silicon atomic force microscopy tip 42. A high temperature step converts the palladium 54 and the silicon 52 from the silicon atomic force microscopy tip 42 at their interface into palladium-silicide 56 (FIG. 8(c)). The unconverted palladium 54 is then removed with a palladium etch, leaving exposed carbon nanotube 12 (FIG. 8(d)). The exposed carbon nanotube 12 is then removed with an oxygen plasma etcher (FIG. 8(e)). Optical analysis (ellipsometry) may be used to very the expected thin films. Finally, a thin layer on the palladium-silicide 56 is electrochemically etched away to expose a short section of nanotube 12 (FIG. 8(f)). The foregoing process enables mass fabrication of structurally strong nanotube-based atomic force microscopy probes that do not need individual shortening prior to imaging.

1. A method for attaching a nanotube to a surface, comprising the steps of:
providing a substrate;
producing at least one trench on said substrate;
growing a nanotube over said trench, wherein a portion of said nanotube suspends said trench;
selectively depositing a film over said trench to rigidly attach said nanotube to said substrate, wherein said film does not cover said portion of said nanotube that suspends said trench and results in a self-aligned attachment of said nanotube to said substrate.

2. The method of claim 1, wherein said substrate comprises SiO₂.

3. The method of claim 1, wherein said film comprises SiO₂.

4. The method of claim 1, wherein said substrate comprises a three-dimensional SiO₂ structure.

5. The method of claim 1, wherein said substrate comprises an atomic force microscopy probe.

6. The method of claim 1, wherein said substrate comprises an oxide structure.

7. The method of claim 1, wherein said step of producing at least one trench comprises producing said trench lithographically.

8. The method of claim 1, wherein said step of producing said trench further comprises a step of producing said trench through e-beam lithography in poly(methyl methacrylate) that is spun onto a SiO₂ substrate

9. The method of claim 8, wherein said step of producing said trench through e-beam lithography further comprises dry etching and transferring the pattern into said SiO₂ substrate resulting in said trench.

10. The method of claim 1, wherein said trench is 150 nm wide.

11. The method of claim 1, wherein said trench is 40 nm deep.

12. The method of claim 1, wherein said step of growing a nanotube over said trench comprises chemical vapor deposition.

13. The method of claim 12, wherein said chemical vapor deposition occurs at 700° C., at atmospheric pressure, and with flow rates of 150 sccm argon, 100 sccm hydrogen and 5.5 sccm ethylene for six minutes.

14. The method of claim 1, wherein said film comprises SiO₂ and is deposited via SiO₂ chemical vapor deposition.

15. The method of claim 1, wherein said step of selectively depositing a film over said trench comprises thermally depositing SiO₂ from a silicon tetra acetate precursor in the reaction Si(O(O)CCH₃)₄(g)→SiO₂(s)+2(CH₃CO)₂O(g).

16. The method of claim 1, further comprising attaching an atomic force microscopy instrument coupled thereto.

17. A nanotube-based nanomechanical device, comprising:
a substrate;
at least one trench on said substrate;
a nanotube grown over said trench, wherein a portion of said nanotube suspends said trench;
a film selectively deposited over said trench and said nanotube to rigidly attach said nanotube to said substrate, wherein said film does not cover said portion of said nanotube that suspends said trench and results in a self-aligned attachment of said nanotube to said substrate.

18. The device of claim 17, wherein said substrate comprises SiO₂.

19. The device of claim 17, wherein said film is SiO₂.

20. The device of claim 17, wherein said substrate comprises a three-dimensional SiO₂ structure.

21. The device of claim 17, wherein said substrate comprises an atomic force microscopy probe.

22. The device of claim 17, wherein said substrate comprises an oxide structure.

23. The device of claim 17, wherein said trench is produced lithographically.

24. The device of claim 17, wherein said trench is produced by e-beam lithography in poly(methyl methacrylate) that is spun onto a SiO₂ substrate

25. The device of claim 24, wherein said trench produced by e-beam lithography in poly(methyl methacrylate) that is spun onto a SiO₂ substrate further comprises etching and transferred a pattern into said SiO₂ substrate resulting in said trench.

26. The device of claim 17, wherein said trench is 150 nm wide and 40 nm deep.

27. The device of claim 17, wherein said nanotube is grown over said trench through chemical vapor deposition.

28. The device of claim 27, wherein said chemical vapor deposition occurs at 700° C., at atmospheric pressure, with flow rates of 150 sccm argon, 100 sccm hydrogen and 5.5 sccm ethylene for six minutes.

29. The device of claim 17, wherein said film comprises SiO₂ and is deposited via SiO₂ chemical vapor deposition.

30. The device of claim 17, wherein said film selectively deposited over said trench results from thermally depositing SiO₂ from a silicon tetra acetate precursor in the reaction Si(O(O)CCH₃)₄(g)→SiO₂(s)+2(CH₃CO)₂O(g).

31. The device of claim 17, further comprising an atomic force microscopy instrument coupled thereto.

32. A method for fabricating a probe for use in atomic force microscopy, comprising:
providing a silicon-based substrate having a tip;
growing a carbon nanotube on said substrate that protrudes from said tip;
depositing a palladium layer on said carbon nanotube and said silicon-based substrate, wherein an interface is created between said palladium layer and said silicon-based substrate;
exposing said silicon-based substrate and said carbon nanotube to a high temperature, wherein said interface between said palladium layer and said silicon-based substrate becomes a palladium silicide, leaving unconverted palladium;
removing said unconverted palladium, leaving a portion of exposed carbon nanotube;
removing said portion of said exposed carbon nanotube, thereby leaving a short section of said carbon nanotube protruding from said tip; and
electrochemically etching away said palladium silicide to expose said short section of said carbon nanotube protruding from said tip.

33. The method of claim 32, wherein said silicon-based substrate comprises a probe for use atomic force microscopy.

34. The method of claim 32, wherein said carbon nanotube is grown using chemical vapor deposition.

35. The method of claim 32, wherein said step of removing said unconverted palladium comprises using a palladium etch.

36. The method of claim 32, wherein said palladium layer is deposited using thermal evaporation.

37. The method of claim 32, wherein step of removing said portion of said exposed carbon nanotube comprises using an oxygen plasma etcher.

38. A probe for use in atomic force microscopy, comprising:
a silicon-based substrate having a tip;
a carbon nanotube grown on said substrate that protrudes from said tip, wherein said carbon nanotube is rigidly attached to said silicon-based substrate by a silicide interface existing between said silicon-based substrate and a layer that was deposited over and heated with said carbon nanotube and said silicon-based substrate;

39. The device of claim 38, wherein said carbon nanotube comprises single walled nanotubes that range in length from 3 to 8 nm.

40. The device of claim 38, wherein said silicon-based substrate comprises a probe for use in atomic force microscopy.

41. The device of claim 38, wherein said carbon nanotube is grown using chemical vapor deposition.

42. The device of claim 38, wherein said layer is deposited using thermal evaporation and comprises palladium.

43. The device of claim 38, wherein said carbon nanotube is shortened by an oxygen plasma etcher.

44. The device of claim 38, wherein silicide from said silicide interface is removed to expose a short section of said carbon nanotube.
